(19) United States
(12) Patent Application Publication
(10) Pub. No.: US 2023/0036358 A1
(43) Pub. Date: Feb. 2, 2023

(54) OPTO-ELECTRIC TRANSMISSION COMPOSITE MODULE AND OPTO-ELECTRIC HYBRID BOARD

(71) Applicant: NITTO DENKO CORPORATION, Osaka (JP)

(72) Inventors: Kazuaki SUZUKI, Osaka (JP); Naoyuki TANAKA, Osaka (JP); Naoto KONEGAWA, Osaka (JP)

(73) Assignee: NITTO DENKO CORPORATION, Osaka (JP)

(21) Appl. No.: 17/792,620

(22) PCT Filed: Jan. 14, 2021
(86) PCT No.: PCT/JP2021/001041

§ 371 Date: Jul. 13, 2022

(30) Foreign Application Priority Data
Jan. 17, 2020 (JP) 2020-006186

(51) Int. Cl. G02B 6/42

(52) U.S. Cl. CPC G02B 6/428; G02B 6/4293; G02B 6/4284

(57) ABSTRACT

Provided is an opto-electric transmission composite module and an opto-electric hybrid board, both of which can suppress the reduction in the function of an optical element when a driver element generates heat. The opto-electric transmission composite module includes: an opto-electric hybrid board including an optical waveguide, and an electric circuit board including a first terminal for mounting an optical element; and a printed wiring board including a fourth terminal for mounting a driver element. The printed wiring board is electrically connected with the electric circuit board.

The present invention relates to an opto-electric transmission composite module and an opto-electric by board.

### BACKGROUND ART

Conventionally, an onto-electric transmission composite module including a printed wiring board, an opto-electric hybrid hoard disposed on the upper surface of the printed wiring board, and a photonic device and a driver element disposed on the upper surface of the opto-electric. hybrid hoard has been known (for example, see Patent document 1 below).

### CITATION LIST

### Patent Document

Patent Document 1: Japanese Unexamined Patent Publication No. 2015-22129

### SUMMARY OF THE INVENTION

### Problem to be Solved by the Invention

However, the driver element generates a lot of heat when the driver element operates. When the heat is transmitted through the opto-electric hybrid board to the optical element, the heat affects the optical element adjacent to the driver element and reduces the function of the optical element.

The present invention provides an opto-electric transmission composite module and an opto-electric hybrid board, both of which can suppress the reduction in the function of the optical element due to the heat generation of the driver element.

### Means for Solving the Problem

The present invention [1] includes an opto-electric transmission composite module comprising: an opto-electric hybrid board including an optical waveguide, and an electric circuit board including a terminal for mounting an optical element; and a printed wiring board electrically connected with the electric circuit board, the printed wiring board including a terminal for mounting a driver element.

In the opto-electric transmission composite module, the optical element is mourned on the opto-electric hybrid board while the driver element is mounted on the printed wiring board. That is, the printed wiring hoard on which the driver element is mounted is separate from the opto-electric hybrid board on which the optical element is mounted. Thus, when the driver element operates and generates heat, the heat of the driver element needs to pass through the two members, i.e., the printed wiring board and the opto-electric hybrid board to reach the optical element. That is, the passing of the heat of the driver element as described above can reduce the heat that reaches the optical element. As a result, the reduction in the function of the optical element can be suppressed.

The present invention [2] includes an opto-electric hybrid board comprising: an optical waveguide; and an electric circuit board, wherein the electric circuit board includes a terminal for mounting an optical element, and a terminal for electrically connecting with a primed wiring board including a driver element mounted on the printed wiring board,

In the opto-electric hybrid board, the electric circuit board includes the terminal for mounting the optical element and the terminal for electrically connecting with the printed wiring board on which the driver element is mounted. The optical element is mounted on the electric circuit board while the driver element is mounted on the printed wiring board. The printed wiring board on which the driver element is mounted is separated from the opto-electric hybrid board on which the optical element is mounted. Thus, when the driver element operates and generates heat, the heat of the driver element needs to pass through the two members, i.e,, the printed wiring board and the opto-electric hybrid board to reach the optical element. This can reduce the heat of the driver element that reaches the optical element. As a result, the reduction in the function of the optical element can be suppressed.

### EFFECTS OF THE INVENTION

The opto-electric transmission composite module and opto-electric hybrid board of the present invention can suppress the reduction in the function of the optical element when the driver element generates heat.

### BRIEF DESCRIPTION OF THE DRAWINGS

FIG. 1A and FIG. 1B are enlarged views of one embodiment of the opto-electric transmission composite module of the present invention. FIG. 1A is a plan view thereof and FIG, 1B is a bottom view.

FIG. 2 is a side view of the opto-electric transmission composite module of FIG. 1A and FIG. 1B, taken along line X-X.

FIG. 3A to FIG. 3D illustrate the steps of producing the opto-electric transmission composite module of FIG. 2. FIG. 3A illustrates a step of preparing an opto-electric hybrid board. FIG. 3B illustrates a step of mounting an optical element on the opto-electric hybrid board. FIG. 3C illustrates a step of preparing a printed wiring board on which a driver element is mounted. FIG. 3D illustrates a step of connecting the printed wiring board to the opto-electric hybrid board.

FIG. 4A and FIG. 4B illustrate a variation of the production steps of FIG. 3A to FIG. 3D. FIG. 4A illustrates a step of preparing an opto-electric hybrid board. FIG. 4B illustrates a step of connecting a printed wiring board to an opto-electric hybrid board.

FIG. 5 illustrates a variation of the opto-electric transmission composite module illustrated in FIG. 2 (a variation in which the printed wiring board and the opto-electric hybrid board are sequentially disposed toward one side in the thickness direction.

### 3DESCRIPTION OF THE EMBODIMENTS

### One Embodiment

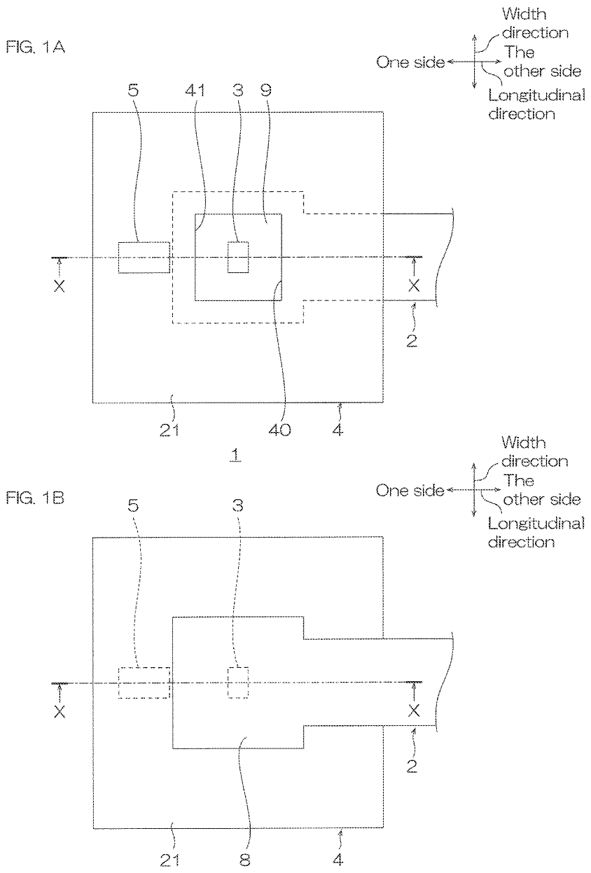

One embodiment of the opto-electric hybrid board of the present invention is described with reference to FIG. 1A to FIG. 3D.

To clarify the relative disposition of an opto-electric hybrid board 2, an optical element 3, a printed wiring board 4, and a driver element 5 (all of them are described below), a first heat dissipating layer 6 (described below) is omitted from FIG. 1A. The optic-electric hybrid board 2, which overlaps the optical element 3, is shown as a dashed line in FIG, 1A,

To clarify the relative disposition of the opto-electric hybrid board 2, the optical element 3, the printed wiring board 4, and the driver element 5, a second heat dissipating layer 7 (described below) was omitted from FIG. 1B. The optical element 3, which overlaps the opto-electric hybrid board 2, and the driver element 5, which overlaps the printed wiring hoard 4, are shown as dashed lines in FIG. 1B.

An opto-electric transmission composite module I has a predetermined thickness, and has an approximately rectangular shape extending in a longitudinal direction. In detail, the opto-electric transmission composite module 1 has a one end portion in the longitudinal direction, which has a larger width than that of each of an intermediate portion and the other end portion in the longitudinal direction (i.e., the one end has a larger length in a width direction orthogonal to a thickness direction and the longitudinal direction).

The opto-electric transmission composite module 1 includes the opto-electric hybrid board 2, the optical element 3, the printed wiring board 4, the driver element 5, the first heat dissipating layer 6, and the second heat dissipating layer 7 exemplifying a heat dissipating layer.

The opto-electric hybrid board 2 has a predetermined thickness, and has an approximately flat belt shape extending in the longitudinal direction. In detail, the opto-electric hybrid board 2 has a one end portion in the longitudinal direction, which has a large width than that of each of an intermediate portion and the other end portion in the longitudinal direction.

The opto-electric hybrid board 2 sequentially includes an optical waveguide 8 and an electric circuit board 9 toward one side in the thickness direction.

The optical waveguide 8 is the other-side portion in the thickness direction of the opto-electric hybrid board 2. The optical waveguide 8 has an outer shape identical to that of the opto-electric hybrid board 2. In other words, the optical waveguide 8 has a shape extending in the longitudinal direction. The optical waveguide 8 includes an under-cladding layer 31, a core layer 32, and an over-cladding layer 33.

The under-cladding layer 31 has a shape identical to the outer shape of the optical waveguide 8 in a plan view.

The core layer 32 is disposed in a central portion in the width direction of the other-side surface in the thickness direction of the under-cladding layer 31, The core layer 32 has a smaller width than that of the under-cladding layer 31 in the plan view.

The over-cladding layer 33 is disposed on the other-side surface in the thickness direction of the under-cladding layer 31 to cover the core layer 32, The over-cladding layer 33 has a shape identical to the outer shape of the under-cladding layer 31 in the plan view. Specifically, the over-cladding layer 33 is disposed on the other-side surface in the thickness direction of the core layer 32 and both side surfaces in the width direction of the core layer 32, and on the other-side surface in the thickness direction of the under-cladding layer 31 at both outsides in the width direction of the core layer 32.

A mirror 34 is formed in a one end portion in the longitudinal direction of the core layer 32,

Examples of the material of the optical waveguide 8 include transparent materials such as epoxy resins. The core layer 32 has a higher refractive index than the refractive index of each of the under-cladding layer 31 and the refractive index of the over-cladding layer 33. The optical waveguide 8 has a thickness of, for example, 20 p,m or more and, for example, 200 pm or less.

The electric circuit board 9 is disposed on a one-side surface in the thickness direction of the optical waveguide 8. In detail, the electric circuit board 9 is in contact with the one-side surface in the thickness direction of the optical waveguide 8. The electric circuit board 9 is a component on which the optical element 3 is mounted in the opto-electric transmission composite module 1. The electric circuit board 9 includes a metal supporting layer 10, an insulating base layer 11, a conductive layer 12, and an insulating cover layer 13.

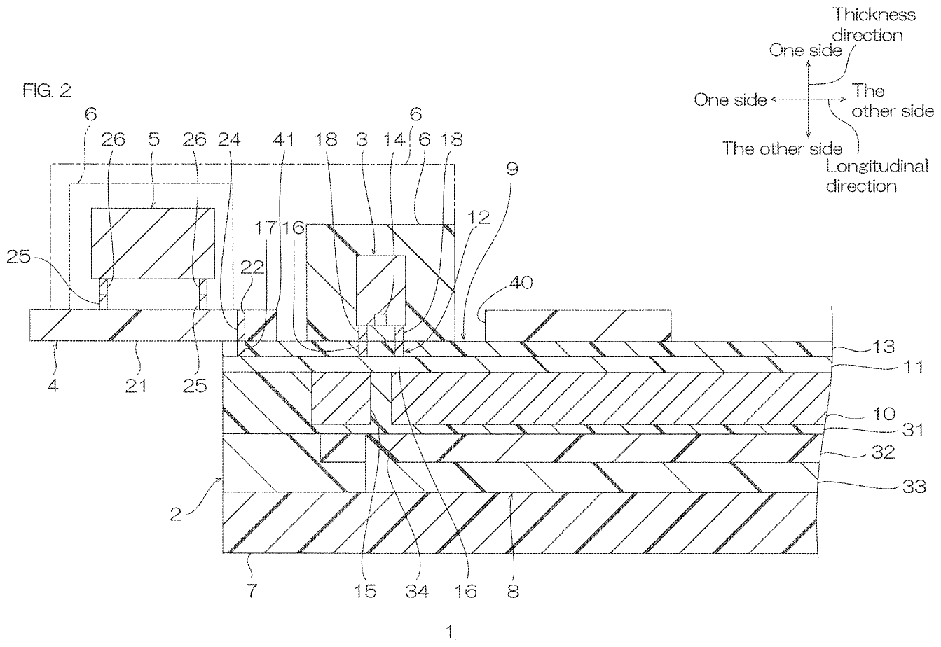

As illustrated in FIG. 2, the metal supporting layer 10 is disposed at the other side in the longitudinal direction relative to a one end region of a one end portion in the longitudinal direction of the electric circuit board 9 in a cross-sectional view. Specifically, the metal supporting layer 10 is located at the other side in the longitudinal direction relative to a side 41 of an opening portion 40 (described below). The other-side surface in the thickness direction of the metal supporting layer 10 is in contact with the under-cladding layer 31. The metal supporting layer 10 has an opening portion 15.

The opening portion 15 is a through-hole penetrating the metal supporting layer 10 in the thickness direction. The opening portion 15 is disposed in the one end portion in the longitudinal direction of the electric circuit board 9. When being projected in the thickness direction, the opening portion 15 overlaps the mirror 34. The metal supporting layer 10 has an inside surface defining the opening portion 15 and being in contact with the under-cladding layer 31.

Examples of the material of the metal supporting layer 10 include metals such as stainless steels, 42 alloys, aluminum, copper-beryllium, phosphor bronze, copper, silver, aluminum, nickel, chromium, titanium, tantalum, platinum, and gold, To achieve excellent thermal conductivity, copper and a stainless steel are preferable. The metal supporting layer 10 has a thickness of, for example, 3 μm or more, preferably 10 μm or more, and, for example, 100 μm or less, preferably 50 μm or less.

The insulating base layer 11 is disposed on a one-side surface in the thickness direction of the metal supporting layer 10. The insulating base layer 11 has an outer shape identical to that of the electric circuit board 9 in the plan view. The insulating base layer 11 has a part protruding at the one side in the longitudinal direction relative to one edge in the longitudinal direction of the metal supporting layer 10 in the cross-sectional view. The other-side surface in the thickness direction of the protruding part of the insulating base layer 11 and the other-side surface in the thickness direction of the opening portion 15 are in contact with the under-cladding layer 31. Examples of the material of the insulating base layer 11 include resins such as polyimide. The insulating base layer 11 has a thickness of, for example, 5 μm or more, and, for example, 50 μm or less, and, in view of heat dissipating property, preferably 40 μm or less, more preferably 30 μm or less.

The conductive layer 12 is disposed at a one-side surface in the thickness direction of the insulating base layer 11. The conductive layer 12 includes a first terminal 16 exemplifying a terminal, a second terminal 17 exemplifying a terminal, and a wire (not illustrated).

The first terminal 16 is provided corresponding to the optical element 3 to be described next. The first terminal 16 is disposed in a central region of the one end portion in the longitudinal direction of the electric circuit board 9. A plurality of the first terminals 16 is provided. The first terminals 16 overlap the metal supporting layer 10 when being projected in the thickness direction.

The second terminal 17 is provided corresponding to the printed wiring board 4 to be described next. The second terminal 17 is disposed at the one side in the longitudinal direction relative to the first terminal 16, being separated by an interval. A plurality of the second terminals 17 is provided. FIG. 2 illustrates only one of the second terminals 17 and does not illustrate all the second terminals 17. However, the second terminals 17 are disposed, for example, along a periphery of the opening portion 40.

The wire not illustrated connects the first terminal 16 and the second terminal 17.

Examples of the material of the conductive layer 12 include conductors such as copper. The conductive layer 12 has a thickness of, for example, 3 μm or more, and, for example, 20 μm or less.

The insulating cover layer 13 is disposed on the one-side surface in the thickness direction of the insulating base layer 11 to cover the wire not illustrated. The insulating cover layer 13 exposes the first terminals 16 and the second terminals 17. Examples of the material of the insulating cover layer 13 include resins such as polyimide.

The insulating cover layer 13 has a thickness of, for example, 5 μm or more, and, for example, 50 μm or less, and, in view of heat dissipating property, preferably 40 μm or less, more preferably 30 μm or less.

As illustrated in FIG. 1A to FIG. 2, the optical element 3 is disposed in the one end portion in the longitudinal direction of the electric circuit board 9. The optical element 3 is mounted on a one-side surface in the thickness direction of the opto-electric hybrid board 2. Examples of the optical element 3 include light-emitting elements and light receiving elements.

A light-emitting element converts electricity into light. Specific examples of the light-emitting element include a vertical-external-cavity surface-emitting-laser (VECSEL). A light-receiving element converts light into electricity. Specific examples of the light-receiving element include a photodiode (PD).

The optical element 3 has an approximately rectangular board shape, The optical element 3 includes an incoming and outgoing port 14 and a first bump 18 on the other-side surface in the thickness direction.

The incoming and outgoing port 14 overlaps the opening portion 15 and the mirror 34 when being projected in the thickness direction.

The first bump 18 is separated from the incoming and outgoing port 14 by an interval in the longitudinal direction. The first bump 18 faces the first terminal 16 in the thickness direction. Coupling the first bump 18 with the first terminal 16 electrically connects the optical element 3 with the electric circuit board 9.

The printed wiring board 4 is disposed in a one end portion in the longitudinal direction of the opto-electric composite transmission module 1, The printed wiring board 4 is different from the opto-electric hybrid board 2. In other words, the printed wiring board 4 is an independent component separately from the opto-electric hybrid board 2, The printed wiring board 4 is a component on which the driver element 5 is mounted in the opto-electric transmission composite module 1. The printed wiring board 4 has an approximately rectangular outer shape larger than the one end portion in the longitudinal direction of the opto-electric hybrid board 2 in the plan view, The printed wiring hoard 4 is disposed at one side in the thickness direction of the opto-electric hybrid board 2. Specifically, the printed wiring board 4 is in contact with the one-side surface in the thickness direction of the opto-electric hybrid board 2.

The printed wiring board 4 includes a board 21, a third terminal 24, a fourth terminal 25 exemplifying a terminal, and a wire not illustrated.

The board 21 has an outer shape identical to that of the printed wiring board 4. The board 21 includes the opening portion 40 and a via 22.

The opening portion 40 penetrates the board 21 in the thickness direction. The opening portion 40 has an approximately rectangular shape in the plan view. The opening portion 40 includes the optical element 3 therein in the plan view. in this manner, the board 21 has an approximately rectangular frame shape surrounding the optical element 3 while holding an interval between the board 21 and the optical element 3 in the plan view.

The via 22 corresponds to the third terminal 24 described below. The via 22 penetrates the board 21 in the thickness direction.

Examples of the material of the board 21 include hard materials such as glass-fiber reinforced epoxy resins.

The via 22 is filled with the third terminal 24. The third terminal 24 extends in the thickness direction. The other-side surface in the thickness direction of the third terminal 24 is exposed from the board 21 to the other side in the thickness direction. The third terminal 24 is electrically connected with the second terminal 17.

The fourth terminal 25 is disposed at one side in the longitudinal direction of the via 22, being separated by an interval. The fourth terminal 25 is disposed on a one-side surface in the thickness direction of the board 21. The fourth terminal 25 extends in the thickness direction. A plurality of the fourth terminals 25 is disposed and separated from each other by an interval.

The wire not illustrated electrically connects the third terminal 24 with the fourth terminal 25 on the one-side surface in the thickness direction of the board 21. The wire not illustrated electrically connects the fourth terminal 25 and another terminal (described below).

Examples of the material of each of the third terminal 24, the fourth terminal 25, and the wire (not illustrated) include conductors such as copper.

The driver element 5 is mounted on the printed wiring board 4. In detail, the driver element 5 is mounted on a one-side surface in the thickness direction of the printed wiring board 4 at one side in the longitudinal direction of the opening portion 40.

The driver element 5 faces the optical element 3 at one side in the longitudinal direction of the optical element 3, holding the side 41 of the one side in the longitudinal direction of the opening portion 40 therebetween, in other words, the driver element 5 is disposed at an opposite side to the optical element 3 with respect to the side 41 of the opening portion 40.

The driver element 5 is an element that is first electrically connected to the opto-electric hybrid board 2 among the members mounted on the printed wiring board 4. In other words, even when an electron element (described below) other than the driver element 5 is mounted on the printed wiring board 4, the driver element 5 is not an element that is connected to the opto-electric hybrid board 2 through the electron element but an element that first exchanges an electrical signal with the opto-electric hybrid board 2 among the members mounted on the printed wiring board 4.

Examples of the driver element 5 include a drive integrated circuit and an impedance converting amplifier circuit. The drive integrated circuit drives a light-emitting element (the optical element 3) by the input of a power source current (electricity). The impedance converting amplifier circuit amplifies the electricity (signal current) of a light receiving element (the optical element 3). The driver element 5 is allowed to generate a lot of heat in operation.

The driver element 5 has an approximately rectangular board shape. The driver element 5 includes a second bump 26 on the other-side surface in the thickness direction.

The second bump 26 extends in the thickness direction. The second bump 26 faces the fourth terminal 25 in the thickness direction. Coupling the second hump 26 with the fourth terminal 25 electrically connects the driver element 5 with the printed wiring board 4.

The electricity output from the driver element 5 is input to the optical element 3 through the fourth terminal 25 and third terminal 24 of the printed wiring board 4 and the second terminal 17 and first terminal 16 of the opto-electric hybrid board 2, and/or the electricity output from the optical element 3 is input to the driver element 5 through the first terminal 16 and second terminal 17 of the opto-electric hybrid board 2 and the third terminal 24 and fourth terminal 25 of the printed wiring board 4.

The opto-electric transmission composite module 1 may include another electron element (not illustrated) mounted on the printed wiring board 4 than the driver element 5. The electron element (not illustrated) transmits an electrical signal to the optical element 3 through the driver element 5. or does not transmit an electrical signal to the optical element 3 and/or from the optical element 3. The electron element is not an element that first exchanges an electrical signal with the opto-electric hybrid board 2 as the driver element 5 does. The electron element has a bump (not illustrated) electrically connected with the printed wiring board 4 through the terminal (other than the fourth terminal 25) included in the printed wiring board 4.

The first heat dissipating layer 6 has a predetermined thickness, and has a shape extending in a surface direction (including the longitudinal direction and the width direction and orthogonal to the thickness direction). The first heat dissipating layer 6 is disposed in an internal part of the opening portion 40 of the printed wiring board 4 on the one-side surface in the thickness direction of the opto-electric hybrid board 2. In other words, the first heat dissipating layer 6 is surrounded by the printed wiring board 4, which defines the opening portion 40, While being separated from the printed wiring board 4 by an interval. The first heat dissipating layer 6 has an approximately rectangular sheet shape in the plan view. The first heat dissipating layer 6 covers the optical element 3. In detail, the first heat dissipating layer 6 is in contact with the one-side surface and peripheral side surface in the thickness direction of the optical element 3, and with the one-side surface in the thickness direction of the opto-electric hybrid board 2 around the optical element 3.

Examples other first heat dissipating layer 6 include heat dissipating sheets, heat dissipating greases, and heat dissipating boards. Examples of the material of the heat dissipating sheet include a filler resin composition in which a filler, such as alumina (aluminum oxide), boron nitride, zinc oxide, aluminum hydroxide, molten silica, magnesium oxide, or aluminum nitride, is dissolved in a resin, such as silicone resin, epoxy resin, acrylic resin, or urethane resin, In such a heat dissipating sheet, for example, the filler may be oriented with respect to the resin in the thickness direction. The resin may include a thermosetting resin and in B stage or C stage. Further, the resin can include a thermoplastic resin. The heat dissipating sheet has an Asker C hardness at 23° C. of, for example, less than 60, preferably 50 or less, more preferably 40 or less, and, for example, 1 or more. The Asker C hardness of the first heat dissipating layer 6 is obtained using an Asker rubber hardness tester C type.

The first heat dissipating layer 6 has a thermal conductivity in the thickness direction of, for example, 3 W/mK or more, preferably 10 W/m·K or more, more preferably 20 W/m·K or more, and, for example, 200 W/m·K or less. The thermal conductivity of the first heat dissipating layer 6 is obtained by a steady-state method in conformity to ASTM-D5470, or by a hot disk method in conformity to ISO-22007-2.

The second heat dissipating layer 7 has a predetermined thickness, and has a shape extending in the surface direction. The second heat dissipating layer 7 is disposed on the other-side surface in the thickness direction of the onto-electric hybrid board 2. In detail, the second heat dissipating layer 7 is in contact with the whole of the other-side surface in the thickness direction of the optical waveguide 8. On the other hand, the second heat dissipating layer 7 does not overlap the driver element 5 when being projected in the thickness direction. The material, properties, and the like of the second heat dissipating layer 7 are the same as those of the first heat dissipating layer 6,

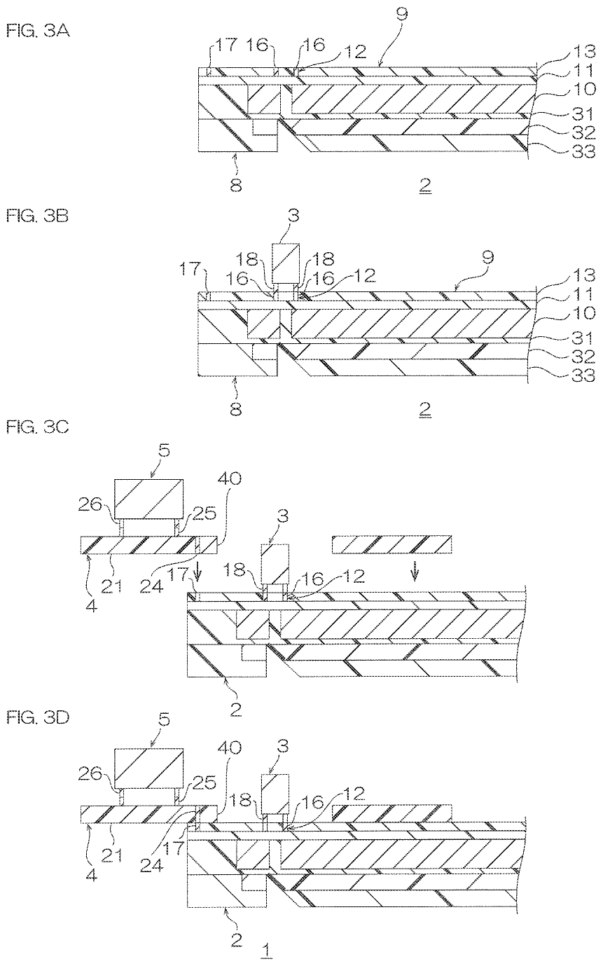

Subsequently, a method of producing the opto-electric hybrid board 2 is described with reference to FIG. 2 through FIG. 3C.

As illustrated in FIG, 3A, first, the opto-electric hybrid board 2 is prepared in this method.

To prepare the opto-electric hybrid board 2, the electric circuit board 9 is prepared first. Subsequently, the optical waveguide 8 is produced to be incorporated in the electric circuit board

To prepare the opto-electric hybrid board 2, a metal sheet (not illustrated) is prepared first. Then, the insulating base layer 11, the conductive layer 12, and the insulating cover layer 13 are prepared and sequentially formed at one side in the thickness direction of the metal sheet.

Thereafter, the outer shape of the metal sheet (not illustrated) is processed, for example, by etching to form the metal supporting layer 10 including the opening portion 15. In this manner, the electric circuit board 9 is prepared.

Subsequently, the optical waveguide 8 is produced to be incorporated in the electric circuit board 9. For example, application of the above-described photosensitive resin composition including a transparent material and photolithography are carried out to sequentially form the under-cladding layer 31, the core layer 32, and the over-cladding layer 33 at the other side in the thickness direction of the electric circuit board 9, in this manner, the optical waveguide 8 is prepared.

In this manner, the opto-electric hybrid board 2 including the optical waveguide 8 and the electric circuit board 9 is prepared.

The optical element 3 is not mounted on the prepared opto-electric hybrid board 2 yet, and the printed wiring board 4 is not connected to the prepared opto-electric hybrid board 2 yet. However, the prepared opto-electric hybrid board 2 can he distributed as a single component and. is an industrially-available device. In the prepared opto-electric hybrid board 2, the first terminal 16 is not connected to the optical element 3 yet, In the opto-electric hybrid board 2, the second terminal 17 is not connected to the printed wiring hoard 4 yet.

Thereafter, as illustrated in FIG. 3B, the optical element 3 is mounted on the electric hybrid board 2. The first bump 18 of the optical element 3 and the first terminal 16 are electrically connected by ultrasonic welding.

In this manner, the optic-electric hybrid board 2 including the optical element 3 mounted thereon is prepared.

Separately, as illustrated in FIG. 3C, the printed wiring board 4 including the driver element 5 mounted thereon is prepared, For example, the fourth terminal 25 is connected to the second bump 26 by reflow. In this manner, the driver element 5 is electrically connected to the printed wiring board 4.

Specifically, to mount the driver element 5 on the printed wiring board 4, the reflow is carried out at a heating temperature of, for example, 150° C. or more, preferably 200° C. or more, more preferably 230° C. or more, and, for example, 300° C. or less, for a heating time of, for example, 1 minute or more, preferably 3 minutes or more, and, for example, 30 minutes or less, preferably 20 minutes or less.

Harsh conditions are preferable for the heating in the mounting of the driver element 5 on the printed wiring board 4 in comparison with the conditions for the connection of the optical element 3 to the opto-electric hybrid board 2. This improves the connection reliability of the driver element 5 to the printed wiring board 4.

Thus, the mounting of the optical element 3 and the mounting the driver element 5 are separately carried out. The conditions for mounting the optical element 3 on the opts-electric hybrid board 2 are softened whereas the conditions for mounting the driver element 5 on the printed wiring board 4 are harshened. This allows for the suppression of the damage to the optical element 3 caused by the heat and the improvement f the connection reliability of the driver element 5 to the printed wiring board 4.

Thereafter, as illustrated in FIG. 3D, the opto-electric hybrid hoard 2 (specifically, the opto-electric hybrid board 2 on which the optical element 3 is mounted) is connected to the printed wiring board 4 (specifically, the printed wiring board 4 on which the driver element 5 is mounted), Specifically, the third terminal 24 is electrically connected to the second terminal 17 by a known method,

Thereafter, as illustrated in FIG. 2, the first heat dissipating layer 6 and the second heat dissipating layer 7 are disposed on the one-side surface and the other side surface in the thickness direction of the opto-electric hybrid board 2, respectively.

In this manner, the opto-electric transmission composite module 1 is produced

### Operations and Effects of One Embodiment

In the opto-electric transmission composite module 1, the optical element 3 is mounted on the opto-electric hybrid board 2 while the driver element 5 is mounted on the printed wiring board 4. The printed wiring board 4 on which the driver element 5 is mounted is separated from the opto-electric hybrid board 2 on which the optical element 3 is mounted. Thus, when the driver element 5 operates and generates heat, the heat of the driver element 5 needs to pass through the two members, i.e., the printed wiring board 4 and the onto-electric hybrid board 2 to reach the optical element 3. The passing of the heat of the driver element 5 as described above can reduce the heat that reaches the optical element 3. As a result, the reduction in the function of the optical element 3 can be suppressed.

### <Variations>

In each of the following variations, the same members and steps as in the above-described embodiment are given the same numerical references and the detailed descriptions thereof are omitted. Further, the variations can have the same operations and effects as those of the embodiment unless especially described otherwise. Furthermore, the embodiment and the variations can appropriately be combined.

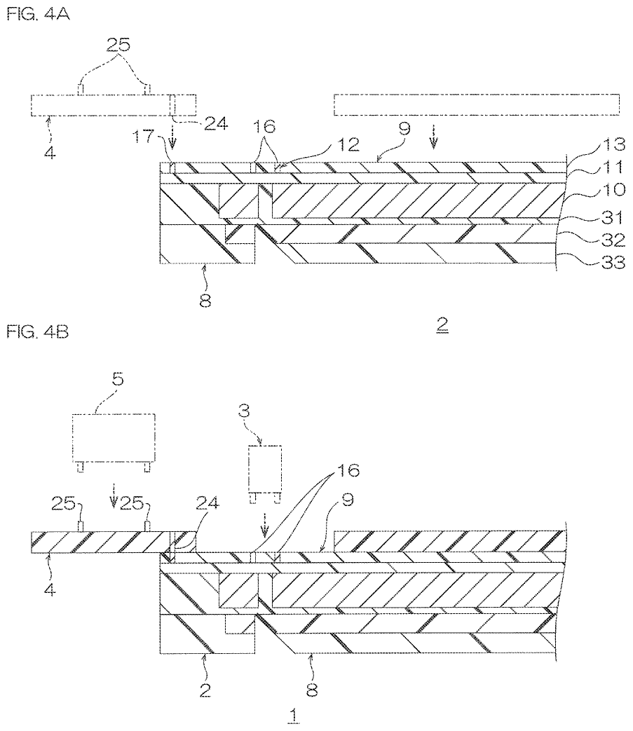

In the steps of producing this variation, as the phantom lines and solid lines of FIG. 4A illustrate, an opto-electric hybrid board 2 and a printed wiring board 4 are prepared first. Subsequently, as illustrated in FIG. 4B, the printed wiring board 4 is electrically connected to an electric circuit board 9 of the opto-electric hybrid board 2.

Specifically, as illustrated in FIG. 4A, the opto-electric hybrid board 2 is prepared first. An optical element 3 is not mounted on the opto-electric hybrid board 2 yet. In other words, the electric circuit board 9 is not electrically connected to the optical element 3 yet.

Next, as illustrated in FIG. 4B. the printed wiring board 4 is connected to the opto-electric hybrid board 2. Specifically, a third terminal 24 of the printed wiring board 4 is electrically connected to a second terminal 17 of the electric circuit board 9 of the opto-electric hybrid board 2.

In this manner, an opto-electric transmission composite module 1 including the opto-electric hybrid board 2 and the printed wiring board 4 is produced.

The opto-electric transmission composite module 1 does not include an optical element 3 and a driver element 5 that are illustrated as the phantom lines of FIG. 4B. However, the electric circuit board 9 of the opto-electric transmission composite module 1 includes a first terminal 16 for mounting the optical element 3. Similarly, the printed wiring board 4 includes a fourth terminal 25 for mounting the driver element 5.

The opto-electric transmission composite module 1 can be distributed as a single module and is an industrially-available device.

The opto-electric transmission composite module 1 of the variation does not include a first heat dissipating layer 6 and a second heat dissipating layer 7.

An optical element 3 and a driver element 5 that are illustrated as the phantom lines of FIG. 4B may be connected to the first terminal 16 and second terminal 17 of the opto-electric transmission composite module 1, respectively.

The opto-electric hybrid board 2 illustrated as the solid lines of FIG. 4A includes the first terminal 16 for mounting the optical element 3 and the second terminal 17 for electrically connecting with the printed wiring board 4 for mounting the driver element 5.

Thus, as the phantom lines of FIG. 4B illustrate, the optical element 3 is mounted on the opto-electric hybrid board 2 and the driver element 5 is mounted on the printed wiring board 4. The printed wiring board 4 on which the driver element 5 is mounted is separated from the opto-electric hybrid board 2 on Which the optical element 3 is mounted. Thus, when the driver element 5 operates and generates heat, the heat of the driver element 5 needs to pass through the two members, i.e., the printed wiring board 4 and the opto-electric hybrid board 2 to reach the optical element 3. Thus, the heat of the driver element 5 that reaches the optical element 3 can be reduced. As a result, the reduction in the function of the optical element 3 can be suppressed.

Although not illustrated, another variation can include only-one of the first heat dissipating layer 6 and the second heat dissipating layer 7.

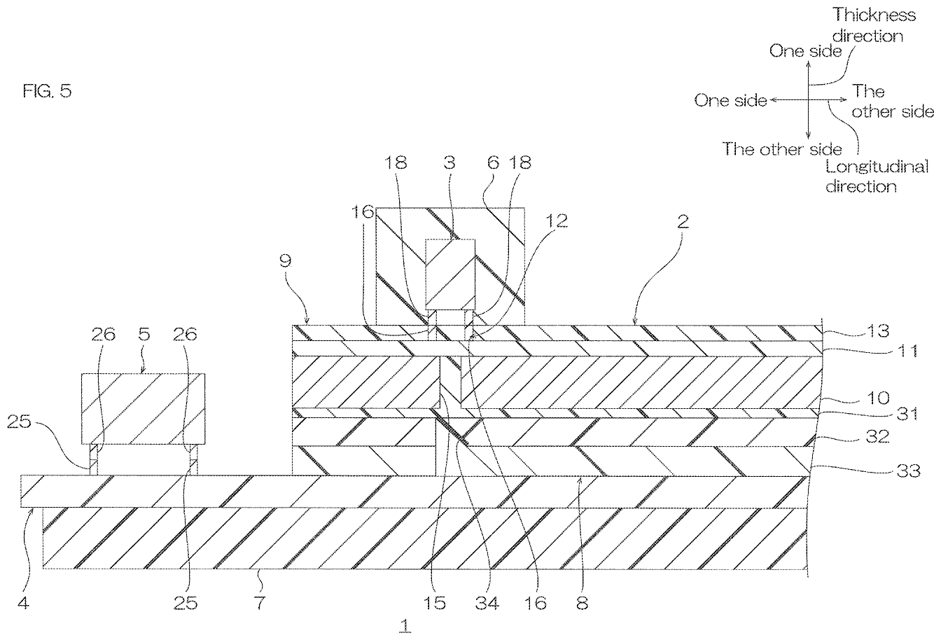

As illustrated in FIG. 5, the opto-electric hybrid board 2 and the printed wiring board 4 can reversely he disposed in the thickness direction. In other words, in this opto-electric transmission composite module 1, the printed wiring board 4 and the opto-electric hybrid board 2 are disposed in this order toward one side in the thickness direction.

The printed wiring board 4 has an approximately rectangular board shape without including the above-described opening portion 40.

The opto-electric hybrid board 2 is in contact with a one-side surface in the thickness direction of the printed wiring board 4.

A driver element 5 is disposed on the one-side surface in the thickness direction of the printed wiring board 4 at the one side in the longitudinal direction of the opto-electric hybrid board 2 while being separated from a one end surface in the longitudinal direction of the opto-electric hybrid board 2 by an interval.

A second heat dissipating layer 7 is in contact with the other-side surface in the thickness direction of the printed wiring board 4. The second heat dissipating layer 7 overlaps both of the optical element 3 and the driver element 5 when being projected in the thickness direction.

A first heat dissipating layer 6 may be in contact with the printed wiring board 4 defining the opening portion 40,

As the alternate long and short dash line of FIG. 2 illustrates, one first heat dissipating layer 6 may be in contact with the optical element 3 and the driver element 5.

As the alternate long and two short dashes line of FIG. 2 illustrates, two first heat dissipating layers 6 (the first heat dissipating layer 6 illustrated as the alternate long and two short dashes line and the first heat dissipating layer 6 illustrated as the alternate long and short dash line) may be in contact with the optical element 3 and the driver element 5, respectively.

While the illustrative embodiments of the present invention are provided in the above description, such is for illustrative purpose only and it is not to be construed as limiting in any manner. Modification and variation of the present invention that will be obvious to those skilled in the art is to be covered by the following claims.

### INDUSTRIAL APPLICABILITY

The opto-electric transmission composite module and opto-electric hybrid board are used for optics and electrics.
1 opto-electric transmission composite module
2 opto-electric hybrid board
3 optical element
4 printed wiring board
5 driver element
7 second heat dissipating layer
16 first terminal
17 second terminal
25 fourth terminal

1. An opto-electric transmission composite module comprising:
an opto-electric hybrid board including
an optical waveguide, and
an electric circuit board including a terminal for mounting an optical element; and
a printed wiring board electrically connected with the electric circuit hoard, the printed wiring board including a terminal for mounting a driver element.

2. An opto-electric hybrid board comprising:
an optical waveguide; and
an electric circuit board, wherein
the electric circuit board includes
a terminal for mounting an optical element, and
a terminal for electrically connecting with a printed wiring board on Which a driver element is mounted.
